(19) United States
(12) Patent Application Publication
(10) Pub. No.: US 2023/0402463 A1
(43) Pub. Date: Dec. 14, 2023

(54) SEMICONDUCTOR DEVICES

(71) Applicant: Samsung Electronics Co., Ltd., Suwon-si (KR)

(72) Inventors: Hoonsung CHOI, Suwon-si (KR); Youngmok Kim, Suwon-si (KR); Sangjin Lee, Suwon-si (KR)

(21) Appl. No.: 18/108,125

(22) Filed: Feb. 10, 2023

(30) Foreign Application Priority Data
Jun. 8, 2022 (KR) 10-2022-0069234

(51) Int. Cl. H01L 27/12; H01L 21/84; H01L 21/8234

(52) U.S. Cl. CPC H01L 27/1207; H01L 21/84; H01L 21/823462

(57) ABSTRACT

A semiconductor device includes a bulk substrate including a first region and a second region, a buried oxide layer and a semiconductor layer stacked on the first region, a first gate structure disposed on the semiconductor layer, a first source/drain layer disposed at an upper portion of the semiconductor layer adjacent to the first gate structure, a second gate structure disposed on the second region, and a second source/drain layer disposed at an upper portion of the bulk substrate adjacent to the second gate structure.

### CROSS-REFERENCE TO RELATED APPLICATION

This application claims priority under 35 U.S.C. § 119 to Korean Patent Application No. 10-2022-0069234, filed on Jun. 8, 2022, in the Korean Intellectual Property Office (KIPO), the disclosure of which is herein incorporated by reference in its entirety.

### TECHNICAL FIELD

Example embodiments of the inventive concept relate to semiconductor devices. More particularly, example embodiments of the inventive concept relate to semiconductor devices having gate structures.

### DISCUSSION OF THE RELATED ART

In a logic device, a contact plug structure may be formed so that a gate structure and a source/drain layer may be connected to upper wirings that apply electrical signals thereto. However, if the gate structure and the source/drain layer do not properly contact the contact plug structure, electrical signals may not be transferred from the upper wirings to the gate structure and the source/drain layer. Furthermore, if there is poor contact between the gate structure and the source/drain layer, the contact resistance between the gate structure and the source/drain layer and the contact plug may increase.

### SUMMARY

Example embodiments of the inventive concept provide a semiconductor device having enhanced characteristics.

According to some embodiments, a semiconductor device includes a bulk substrate including a first region and a second region, a buried oxide layer and a semiconductor layer stacked on the first region, a first gate structure disposed on the semiconductor layer, a first source/drain layer disposed at an upper portion of the semiconductor layer adjacent to the first gate structure, a second gate structure disposed on the second region, and a second source/drain layer disposed at an upper portion of the bulk substrate adjacent to the second gate structure. The first gate structure includes a first gate insulation structure disposed on the semiconductor layer and a first gate electrode disposed on the first gate insulation structure. The second gate structure includes a second gate insulation structure disposed on the bulk substrate and a second gate electrode disposed on the second gate insulation structure. A thickness of the first gate insulation structure is less than a thickness of the second gate insulation structure, and an upper surface of the first gate structure is lower than an upper surface of the second gate structure with respect to a direction perpendicular to an upper surface of the bulk substrate.

According to some embodiments, a semiconductor device includes a bulk substrate including first, second, and third regions a buried oxide layer and a semiconductor layer stacked on the first region, a first gate structure on the semiconductor layer, a first source/drain layer at an upper portion of the semiconductor layer adjacent to the first gate structure, a second gate structure on the second region, a second source/drain layer at an upper portion of the bulk substrate adjacent to the second gate structure, a third gate structure on the third region, a third source/drain layer at an upper portion of the bulk substrate adjacent to the third gate structure. The first gate structure includes a first gate insulation structure and a first gate electrode stacked on the semiconductor layer. The second gate structure includes a second gate insulation structure and a second gate electrode stacked on the bulk substrate. The third gate structure includes a third gate insulation structure and a third gate electrode stacked on the bulk substrate. A thickness of the first gate insulation structure is less than a thickness of the second gate insulation structure, and the thickness of the second gate Insulation structure is less than a thickness of the third gate insulation structure, and an upper surface of the first gate structure is higher than an upper surface of the second gate structure and lower than an upper surface of the third gate structure with respect to an upper surface of the bulk substrate.

According to some embodiments, a semiconductor device includes a bulk substrate including first, second, third, and fourth regions, a first buried oxide layer and a first semiconductor layer stacked on the first region, a second buried oxide layer and a second semiconductor layer stacked on the second region, a first gate structure on the first semiconductor layer, a first source/drain layer at an upper portion of the first semiconductor layer adjacent to the first gate structure, a second gate structure on the second semiconductor layer, a second source/drain layer at an upper portion of the second semiconductor layer adjacent to the second gate structure, a third gate structure on the third region, a third source/drain layer at an upper portion of the bulk substrate adjacent to the third gate structure, a fourth gate structure on the fourth region, a fourth source/drain layer at an upper portion of the bulk substrate adjacent to the fourth gate structure. The first gate structure includes a first gate insulation structure and a first gate electrode stacked on the first semiconductor layer. The second gate structure includes a second gate insulation structure and a second gate electrode stacked on the second semiconductor layer. The third gate structure includes a third gate insulation structure and a third gate electrode stacked on the bulk substrate. The fourth gate structure includes a fourth gate insulation structure and a fourth gate electrode stacked on the bulk substrate. A thickness of the first gate insulation structure is less than a thickness of the second gate insulation structure, the thickness of the second gate insulation structure is less than a thickness of the third gate insulation structure, and the thickness of the third gate insulation structure is less than a thickness of the fourth gate insulation structure.

In the semiconductor device in accordance with example embodiments, the contact plug may contact the gate structure or the source/drain layer. Additionally, the semiconductor device may have an enhanced integration degree.

### BRIEF DESCRIPTION OF THE DRAWINGS

FIG. 1 is a cross-sectional view illustrating a semiconductor device in accordance with example embodiments of the inventive concept.

FIGS. 2, 3, 4, 5, 6, 7, and 8 are cross-sectional views illustrating a method of manufacturing a semiconductor device in accordance with example embodiments of the inventive concept.

### DETAILED DESCRIPTION

A semiconductor device and a method of manufacturing the same in accordance with example embodiments of the inventive concept will be described more fully hereinafter with reference to the accompanying drawings. Hereinafter, in the specification, two directions substantially parallel to an upper surface of a substrate and crossing each other may be referred to as first and second directions D1 and D2, respectively, and a direction substantially perpendicular to the upper surface of the substrate may be referred to as a third direction D3. In example embodiments, the first and second directions D1 and D2 may be substantially perpendicular to each other.

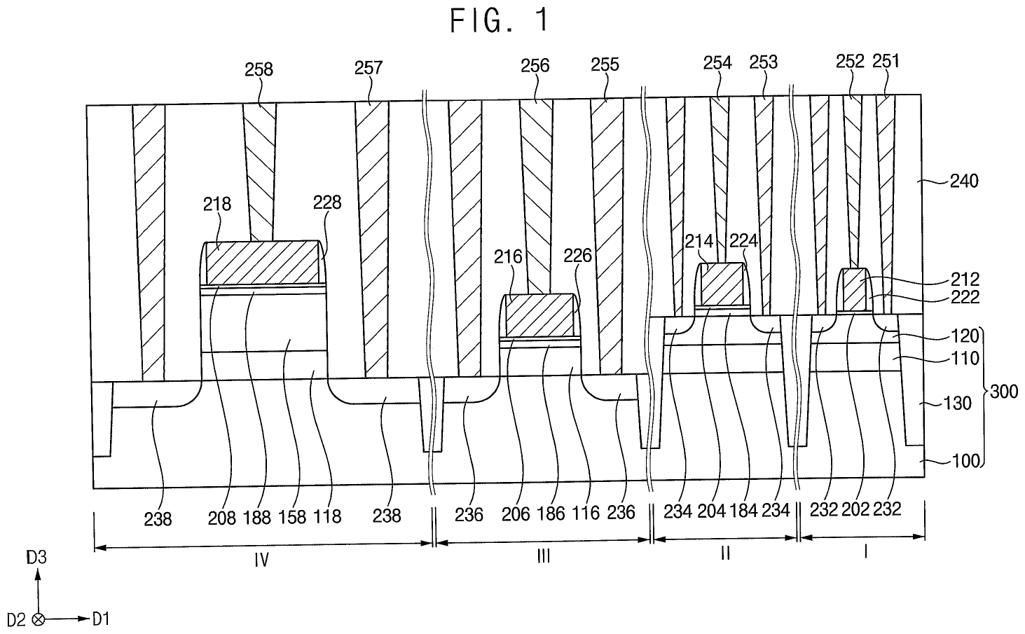

FIG. 1 is a cross-sectional view illustrating a semiconductor device in accordance with example embodiments.

Referring to FIG. 1, the semiconductor device may include first to fourth transistors, first to fourth gate spacers 222, 224, 226, and 228, first to eighth contact plugs 251, 253, 255, 257, 252, 254, 256, and 258, and an insulating interlayer 240 on a substrate structure 300.

In example embodiments, the substrate structure 300 may be a silicon-on-insulator (SOI) substrate. Alternatively, the substrate structure 300 may be a germanium-on-insulator (GOI) substrate.

The substrate structure 300 may include a bulk substrate 100, and a buried oxide layer 110 and a semiconductor layer 120 sequentially stacked on the bulk substrate 100 in the third direction D3. In some cases, semiconductor layer 120 has a direct contact with the buried oxide layer 110, and the buried oxide layer 110 has a direct contact with the bulk substrate 100. In some cases, the buried oxide layer 110 is disposed between semiconductor layer 120 and bulk substrate 100 in the third direction D3. In example embodiments, a thickness of the semiconductor layer 120 may be similar to or less than a thickness of the buried oxide layer 110.

The bulk substrate 100 may include a semiconductor material, e.g., silicon, germanium, and silicon-germanium, etc. the buried oxide layer 110 may include, e.g., silicon oxide, and the semiconductor layer 120 may include, e.g., silicon, germanium, silicon-germanium, etc.

The bulk substrate 100 may include first to fourth regions I, II, III and IV, which may be a first low-voltage region, a second low-voltage region, a middle-voltage region and a high-voltage region, respectively. In example embodiments, voltages applied to the first to fourth regions I, II, III and IV of the bulk substrate 100 may increase successively. That is, the voltage applied to the first region I of the bulk substrate 100 may be less than the voltage applied to the second region II of the bulk substrate 100, the voltage applied to the second region II of the bulk substrate 100 may be less than the voltage applied to the third region III of the bulk substrate 100, and the voltage applied to the third region III of the bulk substrate 100 may be less than the voltage applied to the fourth region IV of the bulk substrate 100.

For example, a voltage equal to or less than about 1V may be applied to the first transistor on the first region I of the bulk substrate 100, a voltage in a range of about 1V to about 5V may be applied to the second transistor on the second region H of the bulk substrate 100, a voltage in a range of about 5V to about 15V may be applied to the third transistor on the third region HI of the bulk substrate 100, and a voltage equal to or more than about 15V may be applied to the fourth transistor on the fourth region IV of the bulk substrate 100.

In example embodiments, the buried oxide layer 110 and the semiconductor layer 120 may be sequentially stacked on the first and second regions I and II of the bulk substrate 100 but not on the third and fourth regions III and IV.

An isolation pattern 130 may be formed on the bulk substrate 100, and the bulk substrate 100 may include a field region on which the isolation pattern 130 is formed and an active region on which not isolation pattern is formed. The field region may not be an active region of the bulk substrate 100.

The first transistor may include a first gate structure and a first impurity region 232 at an upper portion of the semiconductor layer 120 adjacent thereto, the second transistor may include a second gate structure and a second impurity region 234 at an upper portion of the semiconductor layer 120 adjacent thereto, the third transistor may include a third gate structure and a third impurity region 236 at an upper portion of the bulk substrate 100 adjacent thereto, and the fourth transistor may include a fourth gate structure and a fourth impurity region 238 at an upper portion of the bulk substrate 100 adjacent thereto.

In an example embodiment, one or more of the first to fourth gate structures may extend in the second direction D2, and the first to fourth gate structures may be spaced apart from each other in the first direction D1, however, the inventive concept may not be limited thereto. In some examples, the first to fourth gate structures may be disposed at a similar level of height in the third direction D3. In some examples, the first to fourth gate structures may be disposed at different levels of height in the direction D3. However, the inventive concept may not be limited thereto. For example, the first and the second gate structures may be disposed at a similar level of height that is different from the levels of height at which the third and the four gate structures are disposed.

The first gate structure may include a first gate insulation structure on the semiconductor layer 120 and a first gate electrode 212 on the first gate insulation structure, the second gate structure may include a second gate insulation structure on the semiconductor layer 120 and a second gate electrode 214 on the second gate insulation structure, the third gate structure may include a third gate insulation structure on the bulk substrate 100 and a third gate electrode 216 on the third gate insulation structure, and the fourth gate structure may include a fourth gate insulation structure on the bulk substrate 100 and a fourth gate electrode 218 on the fourth gate insulation structure.

One or more of the first to fourth gate electrodes 212, 214, 216, and 218 may include a conductive material, e.g., a metal, a metal nitride, a metal silicide, doped polysilicon, etc.

In example embodiments, widths in the first direction D1 of the first to fourth gate electrodes 212, 214, 216, and 218 may increase successively. For example, a width in the first direction D1 of the first gate electrode 212 may be less than a width in the first direction D1 of the second gate electrode 214, a width in the first direction D1 of the second gate electrode 214 may be less than a width in the first direction D1 of the third gate electrode 216, and a width in the first direction D1 of the third gate electrode 216 may be less than a width in the first direction D1 of the fourth gate electrode 218.

Additionally, lengths in the first direction D1 of the first to fourth gate insulation structures may increase successively. For example, a length in the first direction D1 of the first gate insulation structure may be less than a length in the first direction D1 of the second gate insulation structure, a length in the first direction D1 of the second gate insulation structure may be less than a length in the first direction D1 of the third gate insulation structure, and a length in the first direction D1 of the third gate insulation structure may be less than a length in the first direction D1 of the fourth gate insulation structure.

In example embodiments, the first gate insulation structure may include a first gate insulation pattern 202. The second gate insulation structure may include second and third gate insulation patterns 184 and 204 sequentially stacked in the third direction D3. In some examples, the second gate insulation pattern 204 is on an upper surface of third gate insulation pattern 184 and has a direct contact with the third gate insulation pattern 204. The third gate insulation structure may include fourth to sixth gate insulation patterns 116, 186, and 206 sequentially stacked in the third direction D3, and the sixth gate insulation pattern 206 is on an upper surface of the fifth gate insulation pattern 186, and the fifth gate insulation pattern 186 is on an upper surface of the fourth gate insulation pattern 116. The fourth gate insulation structure may include seventh, eighth, ninth, and tenth gate insulation patterns 118, 158, 188, and 208 sequentially stacked in the third direction D3, and the seventh, eighth, ninth, and tenth gate insulation patterns 118, 158, 188 and 208 may be disposed from bottom to top in the third direction D3.

In example embodiments, the first, third, sixth, and tenth gate insulation patterns 202, 204, 206, and 208 may include substantially a first thickness and material, the second, the fifth, and the ninth gate insulation patterns 184, 186 and 188 may include substantially a second thickness and material, and the fourth and seventh gate insulation patterns 116 and 118 may include substantially a third thickness and material. In some cases, each of the first, the second, and the third thickness and material are substantially the same, but the present disclosure is not limited thereto.

In example embodiments, each of the first to tenth gate insulation patterns 202, 184, 204, 116, 186, 206, 118, 158, 188 and 208 may include, e.g., silicon oxide, and one or more of the the first to tenth gate insulation patterns 202, 184, 204, 116, 186, 206, 118, 158, 188 and 208 neighboring in the third direction D3 may be merged with each other.

In example embodiments, in the first direction D1, a first thickness of the eighth gate insulation pattern 158 may be greater than a second thickness of the fourth and seventh gate insulation patterns 116 and 118, and for example, the first thickness may be equal to or more than twice the second thickness. The second thickness of the fourth and seventh gate insulation patterns 116 and 118 may be greater than a third thickness of the second, fifth and ninth gate insulation patterns 184, 186 and 188, and for example, the second thickness may be equal to or more than twice the third thickness. The third thickness of the second, fifth and ninth gate insulation patterns 184, 186 and 188 may be greater than a fourth thickness of the first, third, sixth and tenth gate insulation patterns 202, 204, 206 and 208, and the third thickness may be equal to or more than twice the fourth thickness.

Thus, the thicknesses of the first to fourth gate insulation structures may increase successively.

In an example embodiment, one or more of the first to fourth impurity regions 232, 234, 236 and 238 may be formed at one or more of opposite sides in the first direction D1 of a corresponding one of the first to fourth gate structures. One or more of the first to fourth impurity regions 232, 234, 236 and 238 may include a semiconductor material doped with, e.g., n-type or p-type impurities.

In example embodiments, the first to fourth gate spacers 222, 224, 226 and 228 may be formed on sidewalls in the first direction D1 of the first to fourth gate electrodes 212, 214, 216 and 218, respectively. One or more of the first to fourth gate spacers 222, 224, 226 and 228 may include an insulating nitride, e.g., silicon nitride.

In example embodiments, an upper surface of the first gate insulation structure may cover lower surfaces of the first gate electrode 212 and the first gate spacer 222, an upper surface of the second gate insulation structure may cover lower surfaces of the second gate electrode 214 and the second gate spacer 224, an upper surface of the third gate insulation structure may cover lower surfaces of the third gate electrode 216 and the third gate spacer 226, and an upper surface of the fourth gate insulation structure may cover lower surfaces of the fourth gate electrode 218 and the fourth gate spacer 228.

In example embodiments, the insulating interlayer 240 may be formed on the substrate structure 300 having the first to fourth transistors thereon, and one or more of the first to eighth contact plugs 251, 253, 255, 257, 252, 254, 256 and 258 may extend through the insulating interlayer 240 in the second direction D2.

In example embodiments, the insulating interlayer 240 may include an oxide, e.g., silicon oxide.

In example embodiments, the first to fourth contact plugs 251, 253, 255 and 257 may contact upper surfaces of the first to fourth impurity regions 232, 234, 236 and 238, respectively, and the fifth to eighth contact plugs 252, 254, 256 and 258 may contact upper surfaces of the first to fourth gate electrodes 212, 214, 216 and 218, respectively.

In example embodiments, the first to fourth gate structures to which different voltages are applied may include the first to fourth gate insulation structures, the first to fourth gate insulation structures having different thicknesses from each other in the second direction D2. For example, the third and fourth gate insulation structures included in the third and fourth transistors, respectively, to which relatively high voltages are applied may have relatively large thicknesses when compared to the thicknesses of the first and second gate insulation structures included in the first and second transistors, respectively, to which relatively low voltages are applied, so that breakdown of the third and fourth gate insulation structures may be prevented.

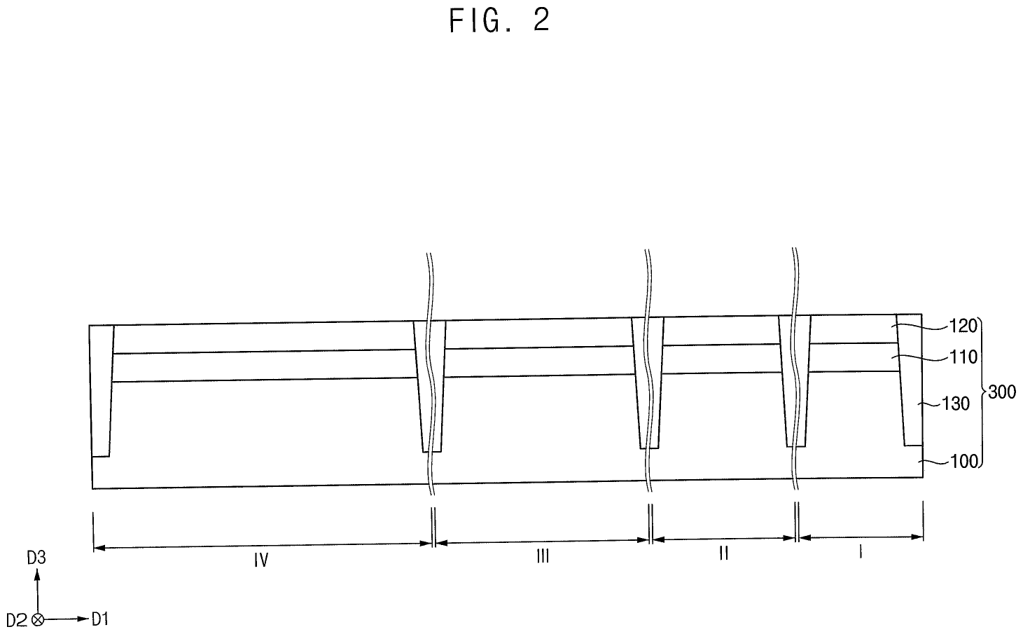

As illustrated below with reference to FIGS. 2 to 8, the first gate insulation structure may include the first gate insulation pattern 202 that may be formed by a deposition process and have a relatively small thickness at least compared with other gate insulation patterns included in the first gate insulation structure, and the second gate insulation structure may include the second and third gate insulation patterns 184 and 204 that may also be formed by a deposition process and have a relatively small thickness at least compared with other gate insulation patterns included in the second gate insulation structure.

In example embodiments, the third gate insulation structure may include the fifth and sixth gate insulation patterns 186 and 206 that may be formed by a deposition process, and further include the fourth gate insulation pattern 116 that may be formed by patterning the buried oxide layer 110 included in an SOI substrate.

In example embodiments, the fourth gate insulation structure may include the ninth and tenth gate insulation patterns 188 and 208 that may be formed by a deposition process, and further include the seventh gate insulation pattern 118 that may be formed by patterning the buried oxide layer 110 included in the SOT substrate, and the eighth gate insulation pattern 158 that may be formed by oxidizing the semiconductor layer 120 included in the SOI substrate and have a volume greater than a volume of the semiconductor layer 120.

Thus, one or more of the third and fourth gate insulation structures may have a relatively large thickness by using the buried oxide layer 110 and the semiconductor layer 120 included in the SOI substrate, instead of a deposition process.

According to some embodiments, given that the third and fourth gate structures include the third and fourth gate insulation structures, respectively, that may have relatively large thicknesses, one or more of the third and fourth gate structures may include the buried oxide layer 110 included in the SOI substrate as a part of a corresponding one of the third and fourth gate insulation structures, and may not include the semiconductor layer 120 on the buried oxide layer 110. For example, an upper surface of the fourth gate structure may not be much higher than upper surfaces of the first and second gate structures, and an upper surface of the third gate structure may be lower than the upper surfaces of the first and second gate structures.

According to some embodiments, heights of the first to fourth gate structures may not have big difference from each other, and thus a thickness of the insulating interlayer 240 may decrease, and the efficiency of a space of the semiconductor device may be enhanced.

According to some embodiments, lengths in the third direction D3 of the first to fourth contact plugs 251, 253, 255 and 257 extending through the insulating interlayer 240 and contacting the upper surfaces of the first to fourth impurity regions 232, 234, 236 and 238, respectively, may not be substantially different from each other, and lengths in the third direction D3 of the fifth to eighth contact plugs 252, 254, 256 and 258 extending through upper portions of the insulating interlayer 240 and contacting the upper surfaces of the first to fourth gate electrodes 212, 214, 216 and 218, respectively, may not be substantially different from each other. Thus, the first to fourth contact plugs 251, 253, 255 and 257 may be formed to establish good contact with the upper surfaces of the first to fourth impurity regions 232, 234, 236 and 238, respectively, and the fifth to eighth contact plugs 252, 254, 256 and 258 may be formed to establish good contact with the upper surfaces of the first to fourth gate electrodes 212, 214, 216 and 218, respectively.

FIGS. 2 to 8 are cross-sectional views illustrating a method of manufacturing a semiconductor device in accordance with example embodiments.

Referring to FIG. 2, a substrate structure 300 may be prepared.

The substrate structure 300 may include a bulk substrate 100, a buried oxide layer 110 and a semiconductor layer 120 sequentially stacked in the third direction D3. In example embodiments, a thickness of the semiconductor layer 120 may be similar to or less than a thickness of the buried oxide layer.

In example embodiments, the bulk substrate 100 may include first to fourth regions I, II, III and IV.

A trench may be formed on the substrate structure 300, and an isolation pattern 130 may be formed in the trench. The isolation pattern 130 may extend through the semiconductor layer 120, the buried oxide layer 110 and an upper portion of the bulk substrate 100 in the direction D3, and thus a lower surface of the isolation pattern 130 may be lower than an upper surface of the bulk substrate 100 in the direction D3.

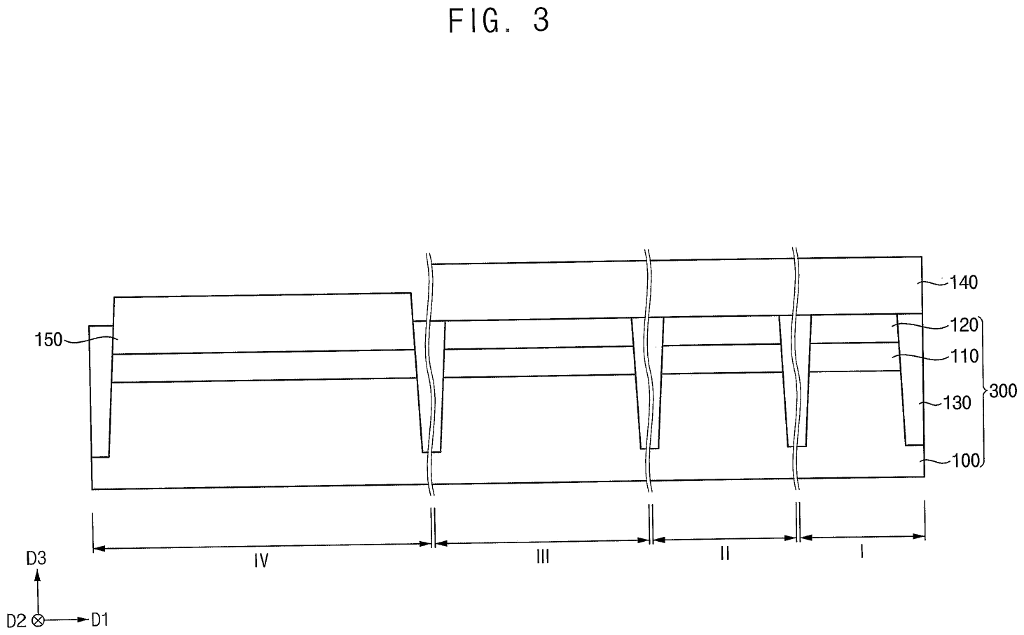

Referring to FIG. 3, a first mask 140 may be formed on portions of the semiconductor layer 120 on the first to third regions I, II and III of the bulk substrate 100 and the isolation pattern 130, and an oxidation process may be performed to form a first gate insulation layer 150 on a portion of the buried oxide layer 110 on the fourth region IV of the bulk substrate 100.

The first mask 140 may include an insulating nitride, e.g., silicon nitride.

In example embodiments, the oxidation process may include a heat treatment process, and in the oxidation process, a portion of the semiconductor layer 120 on the fourth region IV of the bulk substrate 100 not covered by the first mask 140 and including a semiconductor material, e.g., silicon may be oxidized to form the first gate insulation layer 150.

In example embodiments, an initial volume of the portion of the semiconductor layer 120 on the fourth region IV of the bulk substrate 100 may increase to twice the initial volume by the oxidation process, and thus an upper surface of the first gate insulation layer 150 that may be formed from the semiconductor layer 120 may be at a higher level in the third direction D3 than upper surfaces of portions of the semiconductor layer 120 on the portions of the first to third regions I, II and III of the bulk substrate 100.

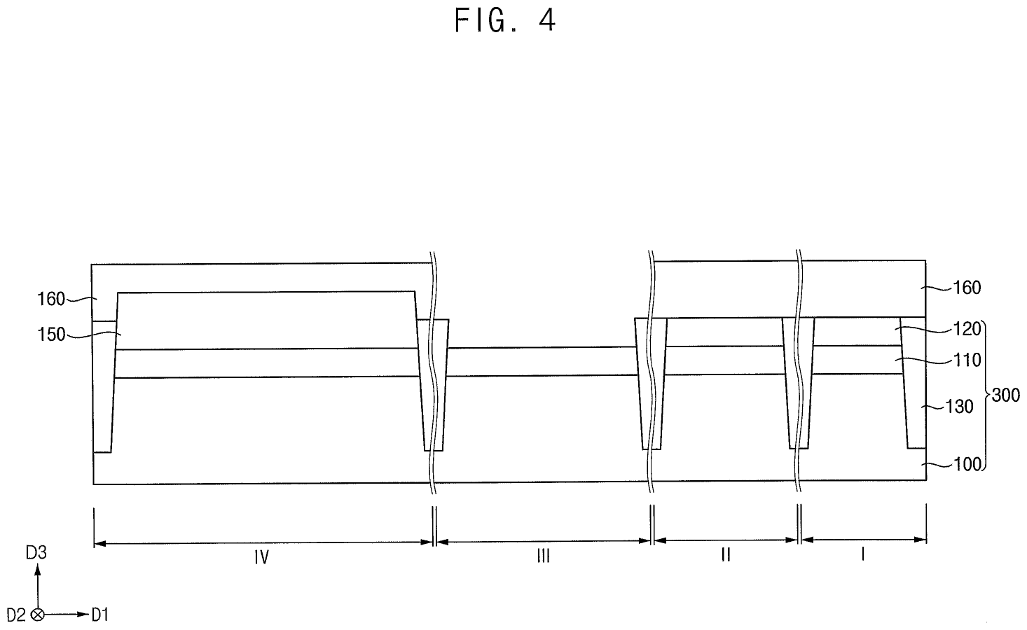

Referring to FIG. 4, after removing the first mask 140, a second mask 160 may be formed on one or more portions of the semiconductor layer 120 on the first, second and fourth regions I, II and IV of the bulk substrate 100. In some example embodiments, a portion of the semiconductor layer 120 not covered by the second mask 160 on the third region III of the bulk substrate 100 may be removed.

The second mask 160 may include a photoresist material, or an insulating nitride, e.g., silicon nitride. The portion of the semiconductor layer 120 on the third region III of the bulk substrate 100 may be removed by a process, e.g., a dry etching process, a wet etching process, etc.

In some example embodiments, after the portion of the semiconductor layer 120 on the third region III of the bulk substrate 100 is removed, an upper surface of a portion of the buried oxide layer 110 thereunder may be exposed.

In an example embodiment, after removing the exposed portion of the buried oxide layer 110 on the third region III of the bulk substrate 100 to expose a portion of the bulk substrate 100, a deposition process may be performed on the exposed portion of the bulk substrate 100 to form a second gate insulation layer. In this case, the buried oxide layer 110 may be replaced with the second gate insulation layer on the third region III of the bulk substrate 100.

Hereinafter, only the case in which the buried oxide layer 110 is not replaced with the second gate insulation layer on the third region III of the bulk substrate 100 is described.

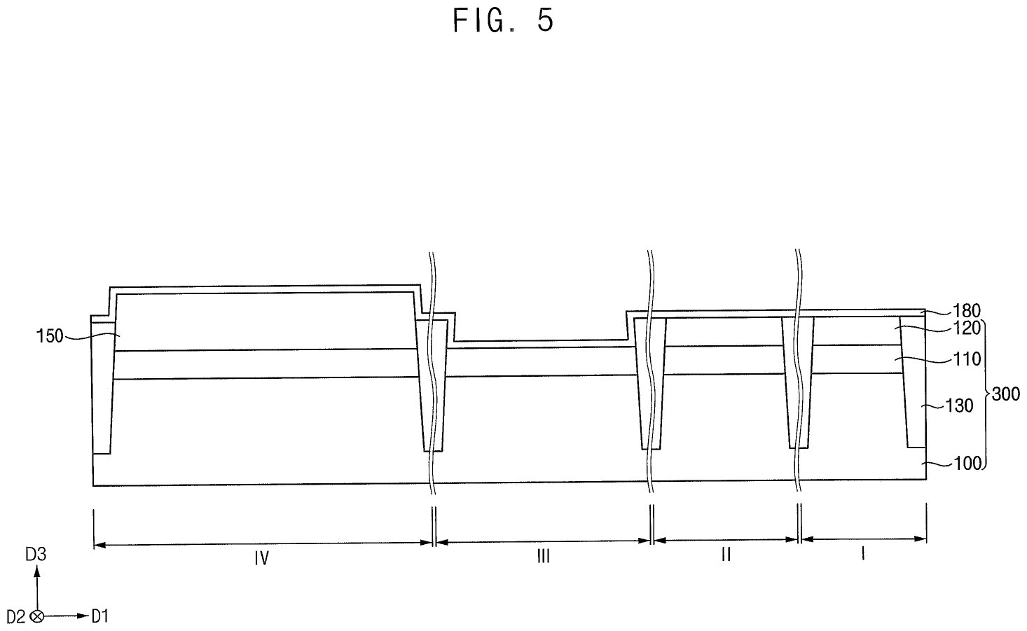

Referring to FIG. 5, after removing the second mask 160, a third gate insulation layer 180 may be formed on locations including portions of the semiconductor layer 120 on the first and second regions I and II of the bulk substrate 100, the portion of the buried oxide layer 110, the first gate insulation layer 150 on the fourth region IV of the bulk substrate 100 and the isolation pattern 130. In example embodiments, the third gate insulation layer may be formed by a process, e.g., a chemical vapor deposition (CVD) process or an atomic layer deposition (ALD) process, etc.

In example embodiments, a thickness of the third gate insulation layer 180 in the first direction D1 may be less than a thickness of the buried oxide layer 110, and for example, the thickness of the third gate insulation layer 180 may be equal to or less than about half the thickness of the buried oxide layer 110.

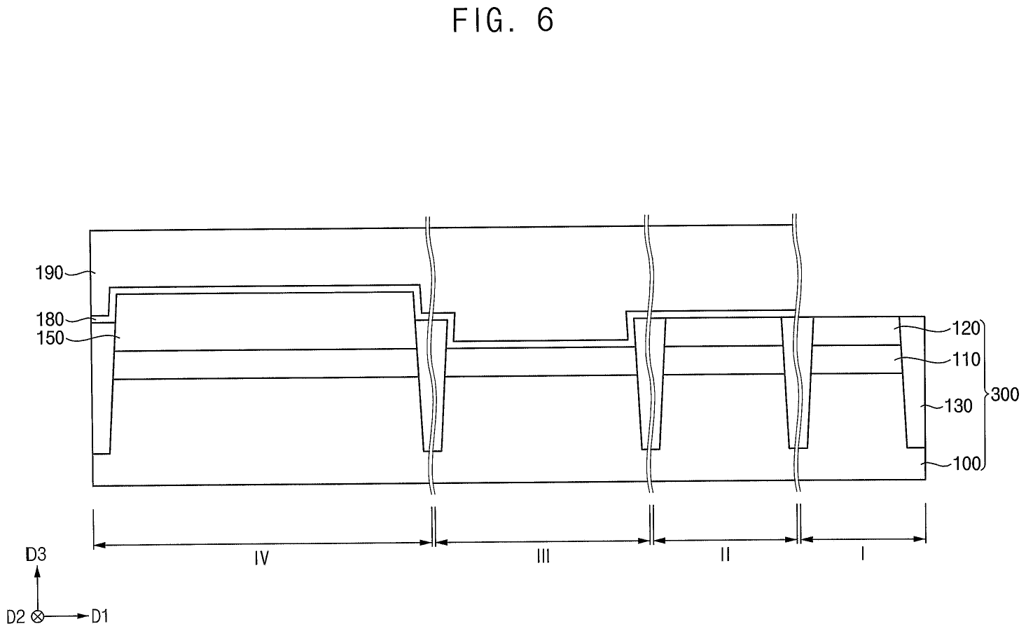

Referring to FIG. 6, a third mask 190 may be formed on portions of the third gate insulation layer 180 on the second to fourth regions II, III and IV of the bulk substrate 100, and the third gate insulation layer180 may be etched using the third mask 190 as an etching mask.

The third mask190 may include a material such as a photoresist material.

Thus, a portion of the third gate insulation layer 180 on the first region I of the bulk substrate 100, which is not covered by the third mask 190, may be removed to expose a portion of the semiconductor layer 120 on the first region I of the bulk substrate 100.

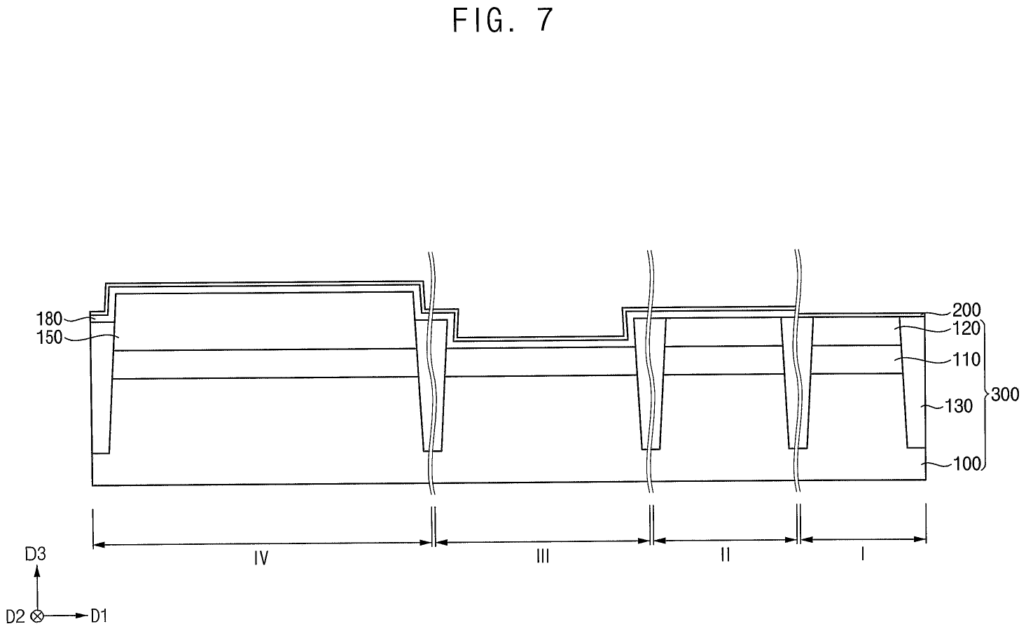

Referring to FIG. 7, after removing the third mask 190, a fourth gate insulation layer 200 may be formed on locations including the portion of the semiconductor layer 120 on the first region I and the portions of the third gate insulation layer 180 on the second to fourth regions II, III and IV, e.g., a CVD process or an ALD process.

In example embodiments, a thickness of the fourth gate insulation layer 200 may be less than a thickness of the third gate insulation layer 180, and for example, the thickness of the fourth gate insulation layer 200 may be equal to or less than about half the thickness of the third gate insulation layer 180.

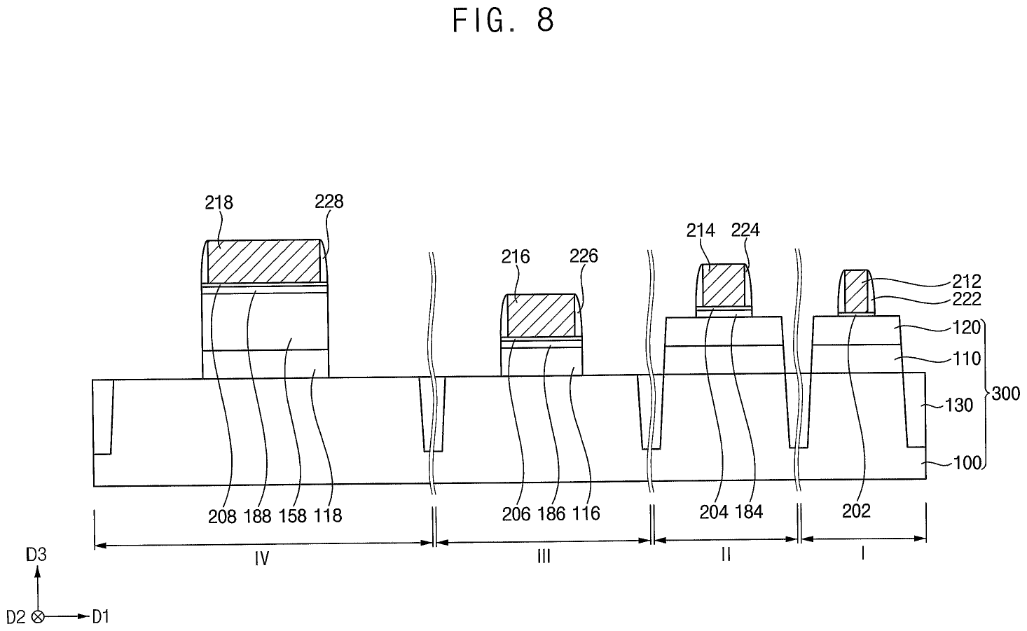

Referring to FIG. 8, a gate electrode layer may be formed on the fourth gate insulation layer 200 on the first to fourth regions I, II, III and IV of the bulk substrate 100, and may be patterned to form the first to fourth gate electrodes 212, 214, 216 and 218, respectively, on the first to fourth regions I, II, III and IV of the bulk substrate 100.

In example embodiments, widths in the first direction D1 of the first to fourth gate electrodes 212, 214, 216 and 218 may increase successively.

A spacer layer may be formed on the third and fourth gate insulation layers 180 and 200 to cover the first to fourth gate electrodes 212, 214, 216 and 218, and may be an isotopically etched to form the first to fourth gate spacers 222, 224, 226 and 228 on sidewalls of the first to fourth gate electrodes 212, 214, 216 and 218, respectively.

The fourth gate insulation layer 200, the third gate insulation layer 180, the first gate insulation layer 150 and the buried oxide layer 110 may be etched using the first to fourth gate electrodes 212, 214, 216 and 218 and the first to fourth gate spacers 222, 224, 226 and 228 as an etching mask.

Thus, a first gate insulation structure including a first gate insulation pattern 202 under the first gate electrode 212 and the first gate spacer 222 may be formed on the buried oxide layer 110 and the semiconductor layer 120 sequentially stacked in the third direction D3 on the first region I of the bulk substrate 100, and a second gate insulation structure including second and third gate insulation patterns 184 and 204 sequentially stacked in the third direction D3 under the second gate electrode 214 and the second gate spacer 224 may be formed on the buried oxide layer 110 and the semiconductor layer 120 sequentially stacked in the third direction D3 on the second region II of the bulk substrate 100.

Additionally, a third gate insulation structure including fourth to sixth gate insulation patterns 116, 186 and 206 sequentially stacked in the third direction D3 under the third gate electrode 216 and the third gate spacer 226 may be formed on the third region III of the bulk substrate 100, and a fourth gate insulation structure including seventh to tenth gate insulation patterns 118, 158, 188 and 208 sequentially stacked in the third direction D3 under the fourth gate electrode 218 and the fourth gate spacer 228 may be formed on the fourth region IV of the bulk substrate 100.

One or more of the first and second gate insulation structures may be formed on the semiconductor layer 120 included in the substrate structure 300, and one or more of the third and fourth gate insulation structures may be formed on the bulk substrate 100 included in the substrate structure 300.

In example embodiments, one or more of the first to tenth gate insulation patterns 202, 184, 204, 116, 186, 206, 118, 158, 188 and 208 may include a material such as silicon oxide. In some examples, a portion of one of the first to tenth gate insulation patterns 202, 184, 204, 116, 186, 206, 118, 158, 188 and 208 may overlap with a portion of another of the first to tenth gate insulation patterns. For example, one insulation pattern may be merged with another insulation pattern.

The first gate electrode 212 and the first gate insulation structure may form a first gate structure, the second gate electrode 214 and the second gate insulation structure may form a second gate structure, the third gate electrode 216 and the third gate insulation structure may form a third gate structure, and the fourth gate electrode 218 and the fourth gate insulation structure may form a fourth gate structure.

In example embodiments, during the etching process, an upper portion of the isolation pattern 130 includes a material such as silicon oxide, and thus an upper surface of the isolation pattern 130 may be substantially coplanar with an upper surface of the bulk substrate 100.

Referring to FIG. 1 again, first and second impurity regions 232 and 234 may be formed at upper portions of the semiconductor layer 120 adjacent to the first and second gate structures, respectively, and third and fourth impurity regions 236 and 238 may be formed at upper portions of the bulk substrate 100 adjacent to the third and fourth gate structures, respectively.

In example embodiments, the first to fourth impurity regions 232, 234, 236 and 238 may be formed by an ion implementation process.

The first gate structure and the first impurity regions 232 at opposite sides of the first gate structure may form a first transistor, the second gate structure and the second impurity regions 234 at opposite sides of the second gate structure may form a second transistor, the third gate structure and the third impurity regions 236 at opposite sides of the third gate structure may form a third transistor, and the fourth gate structure and the fourth impurity regions 238 at opposite sides of the fourth gate structure may form a fourth transistor.

An insulating interlayer 240 may be formed on the first to fourth transistors and the substrate structure 300, and first to fourth contact plugs 251, 253, 255 and 257 extending through the insulating interlayer 240 to contact upper surfaces of the first to fourth impurity regions 232, 234, 236 and 238, respectively, and fifth to eighth contact plugs 252, 254, 256 and 258 extending through the insulating interlayer 240 to contact upper surfaces of the first to fourth gate electrodes 212, 214, 216 and 218, respectively, may be formed to complete the fabrication of the semiconductor device.

As illustrated above, the portion of the semiconductor layer 120 included in the substrate structure 300 on the fourth region IV of the bulk substrate 100 may be transformed into the first gate insulation layer 150 by an oxidation process, and may be patterned to form the eighth gate insulation pattern 158, which is a part of the fourth gate insulation structure. A thickness of the first gate insulation layer 150 that may be formed by the oxidation process from the semiconductor layer 120 may be greater than a thickness of the semiconductor layer 120. Thus, the fourth gate insulation structure having a relatively large thickness may be easily formed when compared to formation of the fourth gate insulation structure by a deposition process.

Additionally, the portion of the semiconductor layer 120 included in the substrate structure 300 on the third region III of the bulk substrate 100 may be removed to expose the portion of the buried oxide layer 110 on the third region III of the bulk substrate 100, and the exposed portion of the buried oxide layer 110 may be patterned to form the fourth gate insulation pattern 116, which is a portion of the third gate insulation structure. Thus, the third gate insulation structure having a relatively large thickness may be easily formed when compared to formation of the third gate insulation structure by a deposition process.

Furthermore, unlike the third and fourth gate structures including the third and fourth gate insulation structures, which may include the buried oxide layer 110 and/or the semiconductor layer 120, one or more of the first and second gate insulation structures may not include a portion of the substrate structure 300, and may be formed on the semiconductor layer 120 included in the substrate structure 300.

Thus, heights of upper surfaces of the first and second gate structures including the first and second gate insulation structures, respectively, having relatively small thicknesses and heights of upper surfaces of the third and fourth gate structures including the third and fourth gate insulation structures, respectively, having relatively large thicknesses do not have big difference from each other. Additionally, heights of upper surfaces of the first and second impurity regions 232 and 234 at upper portions of the semiconductor layer 120 adjacent to the first and second gate structures, respectively, and heights of upper surfaces of the third and fourth impurity regions 236 and 238 at upper portions of the bulk substrate 100 adjacent to the third and fourth gate structures, respectively, are not substantially different from each other.

According to some embodiments, given the third and fourth gate insulation structures include gate insulation patterns that may be formed on the substrate structure 300 instead of the third and fourth gate insulation structures that may be formed from portions of the substrate structure 300, the third and fourth gate insulation structures may have thicknesses much greater than thicknesses of the first and second gate insulation structures, and thus the heights of the upper surfaces of the third and fourth gate structures and the heights of the upper surfaces of the first and second gate structures may be substantially different. Additionally, the heights of the third and fourth impurity regions 236 and 238 and the heights of the first and second impurity regions 232 and 234 may be substantially different. Accordingly, a space of the semiconductor device including the first to fourth gate structures may not be efficiently used to deteriorate the integration degree of the semiconductor device.

Additionally, lengths in the third direction D3 of the first and second contact plugs 251 and 253 contacting the upper surfaces of the first and second impurity regions 232 and 234, respectively, and lengths in the third direction D3 of the third and fourth contact plugs 255 and 257 contacting the upper surfaces of the third and fourth impurity regions 236 and 238, respectively, may be substantially different. Furthermore, lengths in the third direction D3 of the fifth and sixth contact plugs 252 and 254 contacting the upper surfaces of the first and second gate structures, respectively, and lengths in the third direction D3 of the seventh and eighth contact plugs 256 and 258 contacting the upper surfaces of the third and fourth gate structures, respectively, may be substantially different.

Accordingly, during the formation of the first to fourth contact plugs 251, 253, 255 and 257, given the length difference, one or more of the first to fourth contact plugs 251, 253, 255 and 257 may not contact with one or more corresponding impurity regions of the first to fourth impurity regions 232, 234, 236 and 238, and one or more of the fifth to eighth contact plugs 252, 254, 256 and 258 may not contact with one or more corresponding fourth gate structures.

In example embodiments, the height difference between the third and fourth gate structures and the first and second gate structures may decrease so that the semiconductor device including the first to fourth gate structures may have an enhanced integration degree. Additionally, during the formation of the first to fourth contact plugs 251, 253, 255 and 257, the first to fourth contact plugs 251, 253, 255 and 257 may contact the upper surfaces of the first to fourth impurity regions 232, 234, 236 and 238, respectively, and during the formation of the fifth to eighth contact plugs 252, 254, 256 and 258, the fifth to eighth contact plugs 252, 254, 256 and 258 may contact the upper surfaces of the first to fourth gate structures, respectively.

The semiconductor device may be used in various types of memory devices and/or systems including contact plugs. For example, the semiconductor device may be applied to a logic device such as a central processing unit (CPU), an application processor (AP), etc. Alternatively, the semiconductor device may be applied to a volatile memory device such as a DRAM device, an SRAM device, etc., or to a non-volatile memory device such as a flash memory device, a PRAM device, an MRAM device, an RRAM device, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as set forth in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device, comprising:
a bulk substrate including a first region and a second region;
a buried oxide layer and a semiconductor layer stacked on the first region;
a first gate structure disposed on the semiconductor layer;
a first source/drain layer disposed at an upper portion of the semiconductor layer adjacent to the first gate structure;
a second gate structure disposed on the second region; and
a second source/drain layer disposed at an upper portion of the bulk substrate adjacent to the second gate structure,
wherein:
the first gate structure includes:
a first gate insulation structure disposed on the semiconductor layer, and
a first gate electrode disposed on the first gate insulation structure,
the second gate structure includes:
a second gate insulation structure disposed on the bulk substrate; and
a second gate electrode disposed on the second gate insulation structure,
a thickness of the first gate insulation structure is less than a thickness of the second gate insulation structure, and
an upper surface of the first gate structure is lower than an upper surface of the second gate structure with respect to a direction perpendicular to an upper surface of the bulk substrate.

2. The semiconductor device as claimed in claim 1, wherein one or more of the first and second gate structures extend in a second direction substantially parallel to the upper surface of the bulk substrate, and
wherein a width in a first direction of the first gate electrode is less than a width in the first direction of the second gate electrode, the first direction being substantially parallel to the upper surface of the bulk substrate and crossing the second direction.

3. The semiconductor device as claimed in claim 1, wherein one or more of the first and second gate structures extend in a second direction substantially parallel to the upper surface of the bulk substrate, and
wherein a length in a first direction of the first gate insulation structure is less than a length in the first direction of the second gate insulation structure, the first direction being substantially parallel to the upper surface of the bulk substrate and crossing the second direction.

4. The semiconductor device as claimed in claim 1, wherein:
the bulk substrate further includes a third region,
the semiconductor device further comprises:
a third gate structure disposed on the third region; and
a third source/drain layer disposed at an upper portion of the bulk substrate adjacent to the third gate structure,
the third gate structure includes:
a third gate insulation structure disposed on the bulk substrate; and
a third gate electrode disposed on the third gate insulation structure, and
a thickness of the third gate insulation structure is greater than the thickness of the first gate insulation structure and smaller than the thickness of the second gate insulation structure.

5. The semiconductor device as claimed in claim 4, wherein an upper surface of the third gate structure is lower than the upper surface of the first gate structure.

6. The semiconductor device as claimed in claim 4, wherein the first gate structure and the first source/drain layer form a first transistor, the second gate structure and the second source/drain layer form a second transistor, and the third gate structure and the third source/drain layer form a third transistor, and
wherein a voltage applied to the third transistor is greater than a voltage applied to the first transistor and smaller than a voltage applied to the second transistor.

7. The semiconductor device as claimed in claim 4, wherein one or more of the first to third gate structures extends in a second direction substantially parallel to the upper surface of the bulk substrate, and
wherein a width in a first direction of the third gate electrode is greater than a width in the first direction of the first gate electrode and smaller than a width in the first direction of the second gate electrode, the first direction being substantially parallel to the upper surface of the bulk substrate and crossing the second direction.

8. The semiconductor device as claimed in claim 4, wherein one or more of the first to third gate structures extends in a second direction substantially parallel to the upper surface of the bulk substrate, and
wherein a length in a first direction of the third gate insulation structure is greater than a length in the first direction of the first gate insulation structure and smaller than a length in the first direction of the second gate insulation structure, the first direction being substantially parallel to the upper surface of the bulk substrate and crossing the second direction.

9. The semiconductor device as claimed in claim 1, wherein:
the bulk substrate further includes a third region, and the buried oxide layer and the semiconductor layer are stacked on the third region,
the semiconductor device further comprises:
a third gate structure on a portion of the semiconductor layer on the third region; and
a third source/drain layer at an upper portion of the semiconductor layer adjacent to the third gate structure,
the third gate structure includes:
a third gate insulation structure on the portion of the semiconductor layer; and
a third gate electrode on the third gate insulation structure, and
a thickness of the third gate insulation structure is less than the thickness of the first gate insulation structure.

10. The semiconductor device as claimed in claim 9, wherein an upper surface of the third gate structure is lower than the upper surface of the first gate structure.

11. The semiconductor device as claimed in claim 9, wherein the first gate structure and the first source/drain layer form a first transistor, the second gate structure and the second source/drain layer form a second transistor, and the third gate structure and the third source/drain layer form a third transistor, and
wherein a voltage applied to the third transistor is less than a voltage applied to the first transistor and smaller than a voltage applied to the second transistor.

12. The semiconductor device as claimed in claim 1, wherein:
one or more of the first and second gate structures extends in a second direction substantially parallel to the upper surface of the bulk substrate,
the semiconductor device further comprises:
a first gate spacer on one or more of opposite sidewalls in a first direction of the first gate electrode, the first direction being substantially parallel to the upper surface of the bulk substrate and crossing the second direction; and
a second gate spacer on one or more of opposite sidewalls in the first direction of the second gate electrode, and
the first gate insulation structure covers lower surfaces of the first gate electrode and the first gate spacer, and the second gate insulation structure covers lower surfaces of the second gate electrode and the second gate spacer.

13. A semiconductor device, comprising:
a bulk substrate including first, second, and third regions;
a buried oxide layer and a semiconductor layer stacked on the first region;
a first gate structure on the semiconductor layer;
a first source/drain layer at an upper portion of the semiconductor layer adjacent to the first gate structure;
a second gate structure on the second region;
a second source/drain layer at an upper portion of the bulk substrate adjacent to the second gate structure;
a third gate structure on the third region;
a third source/drain layer at an upper portion of the bulk substrate adjacent to the third gate structure,
wherein:
the first gate structure includes a first gate insulation structure and a first gate electrode stacked on the semiconductor layer,
the second gate structure includes a second gate insulation structure and a second gate electrode stacked on the bulk substrate,
the third gate structure includes a third gate insulation structure and a third gate electrode stacked on the bulk substrate,
a thickness of the first gate insulation structure is less than a thickness of the second gate insulation structure, and the thickness of the second gate insulation structure is less than a thickness of the third gate insulation structure, and
an upper surface of the first gate structure is higher than an upper surface of the second gate structure and lower than an upper surface of the third gate structure with respect to an upper surface of the bulk substrate.

14. The semiconductor device as claimed in claim 13, wherein:
one or more of the first to third gate structures extends in a second direction substantially parallel to an upper surface of the bulk substrate,
a width in a first direction of the first gate electrode is less than a width in the first direction of the second gate electrode, the first direction being substantially parallel to the upper surface of the bulk substrate and crossing the second direction, and
the width in the first direction of the second gate electrode is less than a width in the first direction of the third gate electrode.

15. The semiconductor device as claimed in claim 13, wherein:
one or more of the first to third gate structures extends in a second direction substantially parallel to the upper surface of the bulk substrate,
a length in a first direction of the first gate insulation structure is less than a length in the first direction of the second gate insulation structure, the first direction being substantially parallel to the upper surface of the bulk substrate and crossing the second direction, and
the length in the first direction of the second gate insulation structure is less than a length in the first direction of the third gate insulation structure.

16. The semiconductor device as claimed in claim 13, wherein:
one or more of the first to third gate structures extends in a second direction substantially parallel to the upper surface of the bulk substrate,
the semiconductor device further comprises:
a first gate spacer on one or more opposite sidewalls in a first direction of the first gate electrode, the first direction being substantially parallel to the upper surface of the bulk substrate and crossing the second direction;
a second gate spacer on one or more opposite sidewalls in the first direction of the second gate electrode; and
a third gate spacer on one or more opposite sidewalls in the first direction of the third gate electrode, and
the first gate insulation structure covers lower surfaces of the first gate electrode and the first gate spacer, the second gate insulation structure covers lower surfaces of the second gate electrode and the second gate spacer, and the third gate insulation structure covers lower surfaces of the third gate electrode and the third gate spacer.

17. A semiconductor device, comprising:
a bulk substrate including first, second, third, and fourth regions;
a first buried oxide layer and a first semiconductor layer stacked on the first region;
a second buried oxide layer and a second semiconductor layer stacked on the second region;
a first gate structure on the first semiconductor layer;
a first source/drain layer at an upper portion of the first semiconductor layer adjacent to the first gate structure;
a second gate structure on the second semiconductor layer;
a second source/drain layer at an upper portion of the second semiconductor layer adjacent to the second gate structure;
a third gate structure on the third region;
a third source/drain layer at an upper portion of the bulk substrate adjacent to the third gate structure;
a fourth gate structure on the fourth region;
a fourth source/drain layer at an upper portion of the bulk substrate adjacent to the fourth gate structure,
wherein:
the first gate structure includes a first gate insulation structure and a first gate electrode stacked on the first semiconductor layer,
the second gate structure includes a second gate insulation structure and a second gate electrode stacked on the second semiconductor layer,
the third gate structure includes a third gate insulation structure and a third gate electrode stacked on the bulk substrate;
the fourth gate structure includes a fourth gate insulation structure and a fourth gate electrode stacked on the bulk substrate, and
a thickness of the first gate insulation structure is less than a thickness of the second gate insulation structure, the thickness of the second gate insulation structure is less than a thickness of the third gate insulation structure, and the thickness of the third gate insulation structure is less than a thickness of the fourth gate insulation structure.

18. The semiconductor device as claimed in claim 17, wherein an upper surface of the third gate structure is lower than an upper surface of the first gate structure with respect to an upper surface of the bulk substrate, the upper surface of the first gate structure is lower than an upper surface of the second gate structure with respect to the upper surface of the bulk substrate, and the upper surface of the second gate structure is lower than an upper surface of the fourth gate structure with respect to the upper surface of the bulk substrate.

19. The semiconductor device as claimed in claim 17, wherein:
one or more of the first to fourth gate structures extends in a second direction substantially parallel to an upper surface of the bulk substrate,
a width in a first direction of the first gate electrode is less than a width in the first direction of the second gate electrode, the width in the first direction of the second gate electrode is less than a width in the first direction of the third gate electrode, and the width in the first direction of the third gate electrode is less than a width in the first direction of the fourth gate electrode, and
the first direction is substantially parallel to the upper surface of the bulk substrate and crosses the second direction.

20. The semiconductor device as claimed in claim 17, wherein:
one or more of the first to third gate structures extends in a second direction substantially parallel to an upper surface of the bulk substrate,
a length in a first direction of the first gate insulation structure is less than a length in the first direction of the second gate insulation structure, the length in the first direction of the second gate insulation structure is less than a length in the first direction of the third gate insulation structure, and the length in the first direction of the third gate insulation structure is less than a length in the first direction of the fourth gate insulation structure, and
the first direction is substantially parallel to the upper surface of the bulk substrate and crosses the second direction.
